(19) United States
(12) Patent Application Publication
(10) Pub. No.: US 2016/0005712 A1
(43) Pub. Date: Jan. 7, 2016

(54) STRUCTURE AND METHOD OF PACKAGED SEMICONDUCTOR DEVICES WITH BENT-LEAD QFN LEADFRAMES

(71) Applicant: Texas Instruments Incorporated, Dallas, TX (US)

(72) Inventors: Andy Quang Tran, Plano, TX (US); Reynaldo Corpuz Javier, Plano, TX (US); Alok Kumar Lohia, Dallas, TX (US)

(21) Appl. No.: 14/854,886

(22) Filed: Sep. 15, 2015

Related U.S. Application Data
(62) Division of application No. 14/213,042, filed on Mar. 14, 2014.

(51) Int. Cl. H01L 23/00; H01L 21/78; H01L 21/56; H01L 21/48

(52) U.S. Cl. CPC H01L 24/97; H01L 21/4842; H01L 21/78; H01L 21/561; H01L 21/4825; H01L 21/4835; H01L 24/83; H01L 2924/1715; H01L 2924/1711

(57) ABSTRACT

A method for fabricating a semiconductor device package provides a metallic leadframes with a plurality of device sites. Each site including a pad and a plurality of leads with solderable surfaces. At least one set of leads are aligned in a row and are connected by rails to respective leads of an adjacent site. The leads and rails of the row having a surface in a common plane. The strip with the assembled sites and connecting rails are encapsulated in a packaging material, leaving the common-plane lead and rail surfaces un-encapsulated. Trenches are cut between adjacent sites by removing packaging material until reaching the rails. Thus, creating sidewalls of device packages connected by rails. Device packages are singulated from the strip by severing the connecting rails between adjacent sites in approximate halves, leaving a respective rail half as a straight protrusion attached to each lead. The protrusions are bent at an angle away from the common plane towards the package sidewall.

### CROSS REFERENCE TO RELATED APPLICATIONS

This application is a Divisional of and claims priority to U.S. Patent Application Ser. No. 14/213,042, filed Mar. 14, 2014. Said application incorporated herein by reference for its entirety.

### FIELD

The embodiments of the invention are related in general to the field of semiconductor devices and processes, and more specifically to the structure and fabrication method of packaged semiconductor devices with QFN/SON leadframes having bent leads.

### DESCRIPTION OF RELATED ART

The structure of contact pad metallizations and solder bumps for connecting integrated circuit (IC) chips to semiconductor packages or outside parts, as well as the thermomechanical stresses and reliability risks involved, have been described in a series of detailed publications, especially by IBM researchers (1969). During and after assembly of the IC chip to an outside part by solder reflow and then during device operation, significant temperature differences and temperature cycles appear between semiconductor chip and the substrate. The reliability of the solder joint is strongly influenced by the coefficients of thermal expansion of the semiconductor material and the substrate material. For example, there is more than one order of magnitude difference between the coefficients of thermal expansion of silicon and FR-4 and laminated boards. This difference causes thermomechanical stresses, which the solder joints have to absorb. Detailed calculations involving the optimum height and volume of the solder connection and the expected onset of fatigue and cracking proposed a number of solder design solutions.

The fabrication methods and reliability problems involving flip-chips re-appear in somewhat modified form for ball-grid array type packages and chip-scale and chip-size packages, which may be attached directly to a printed circuit board (PCB), or alternatively, coupled to a second interconnection surface such as an interposer. Attaching the ball grid array to the next interconnect is carried out by aligning the solder bumps or balls on the package to contact pads on the interconnection and then performing a solder reflow operation. During the reflow, the bumps or balls liquefy and make a bond to the next interconnect level which has pads or traces to receive the solder. Following the solder reflow step, a polymeric underfill is often used between the package and the interposer (or PCB) to alleviate mechanical stress caused by the mismatch in the coefficients of thermal expansion (CTE) between the package, the interposer, if any, and the PCB. Many reliability problems occur due to the stress placed on the solder bumps or balls when the assembly is cycled from hot to cool during operation.

In one method of drastically reducing the thermomechanical stress on the solder bumps, a sheet-like compliant elastomer substantially de-couples the solder bumps, affixed to the outside PCB, from the IC chip and the interposer, thus relieving the thermal mismatch. Drawbacks of this method are assembly hurdles and cost considerations. Another method aims at absorbing part of the thermomechanical stress on the solder joints by plastic material surrounding the joints and filling the gap between chip and substrate. However, the underfilling method represents an unwelcome process step after device attachment to the motherboard.

In yet another wafer-level process, a flux-impregnated epoxy is screened on the wafer, with openings for the chip contact pads. The solder balls are placed on the pads; during the reflow process, the epoxy softens and forms a fillet, or collar, at the base of the solder ball, where stress-induced cracks typically originate. The wafer-level process with the required high temperature of solder reflow cannot be transferred to individual plastic packages.

The thermomechanical stress problems experienced at solder joints in ball-grid array devices re-appear in devices, which use QFN/SON-type leadframes. The name of these leadframes (Quad Flat No-lead, Small Outline No-lead) indicates that the leads do not have cantilevered leads, but flat leads, which are typically arrayed along the periphery of the packaged device. The metal of the leads is connected by solder material to the metal of respective contact pads of the external part. Even when the solder joints are not formed by solder balls but rather by solder layers, the nature of the thermomechanical stress at the joints derives from the mismatch of the coefficients of thermal expansion among the various materials. When plastic-packaged semiconductor devices with QFN/SON-type leadframes, attached to externals parts by solder balls or solder layers, are subjected to accelerating reliability tests such as temperature cycling, it is known that units may fail due to stress-induced microcracks through the solder joints.

### SUMMARY

Applicants' failure analysis of microcracks in solder joints of semiconductor devices with QFN/SON-type leadframes revealed that solder cracks typically originate in the region of high stress concentration in conjunction with small metal burrs created in the sawing or singulation processes of molded semiconductor packages. The sawing step after the packaging process uses rotating saws to form discrete devices from leadframe strips by sawing through the plastic compound and the metallic connecting rails between adjacent devices, fraying the metal into occasional burrs. In addition, applicants found that the burrs frequently hinder the forming of a solder meniscus at the freshly exposed lead sidewalls, thereby depriving the nascent solder joint of strong fillets needed to create robust joints, which can withstand the high thermomechanical stresses during the reliability tests.

Applicants solved the problems of avoiding burrs and enabling robust solder meniscus, when they discovered a method of lead formation, which not only avoids burrs but also enlarges the solderable area of the lead so that strong solder fillets form automatically and solder joints with constrictions are avoided. In the method, leads of one device site, aligned in a row, are connected by rails to respective leads of an adjacent site; the leads and rails of the row have solderable surfaces with one surface in a common plane. After encapsulation in a packaging compound while leaving the leads and rails in the common plane un-encapsulated, a saw is cutting trenches in the packaging compound between adjacent leads until the saw reaches the rails. Then, a sharp tool cuts the connecting rails in approximate halves, leaving a respective rail half as a straight metal protrusion attached to each lead. Finally, an apparatus with angled wings bends the metal protrusions at an acute or right angle away from the common plane towards the device package. Solder joints can now form not only with the solderable surface of the lead, but also with the bent protrusion.

Alternatively, the straight metal protrusions may be produced by other techniques, which include methods for creating trenches in package material by ablation and sputtering, and severing leadframe rails by cleaving and breaking.

### BRIEF DESCRIPTION OF THE DRAWINGS

FIG. 1 illustrates a cross section of a packaged semiconductor device with a QFN/SON-type leadframe and bent lead-protrusions solder-attached to a substrate.

FIG. 2 shows a cross section of a portion of a QFN/SON-type leadframe strip with rails connecting respective leads of adjacent device sites.

FIG. 3 depicts a cross section of a portion of a leadframe strip with rails connecting respective leads and assembled semiconductor chips encapsulated in a packaging compound.

FIG. 4 illustrates a cross section of the leadframe strip of FIG. 3 during the process step of a saw blade cutting trenches into the packaging compound until reaching the rails.

FIG. 5 shows a cross section of the leadframe strip of FIG. 4 with trenches in the packaging compound cut to the rails.

FIG. 6 depicts a cross section of the leadframe strip of FIG. 5 during the process step of cleaning the trenches in the packaging compound.

FIG. 7 illustrates a cross section of a portion of the leadframe strip of FIG. 6 during the process step of cutting the rails in approximate halves, leaving a respective rail half as a protrusion attached to each lead.

FIG. 8 shows a cross section of a singulated device of the leadframe strip of FIG. 7, with the straight protrusions of the leads ready to be bent in an apparatus for metal forming.

FIG. 9 depicts the device of FIG. 8 after the process step of bending the protrusions at an acute angle in an apparatus providing a tool with obtuse angles.

FIG. 10 illustrates the device of FIG. 8 after the process step of bending the protrusions at a right angle in an apparatus providing a tool with right angles.

### DETAILED DESCRIPTION OF THE PREFERRED EMBODIMENTS

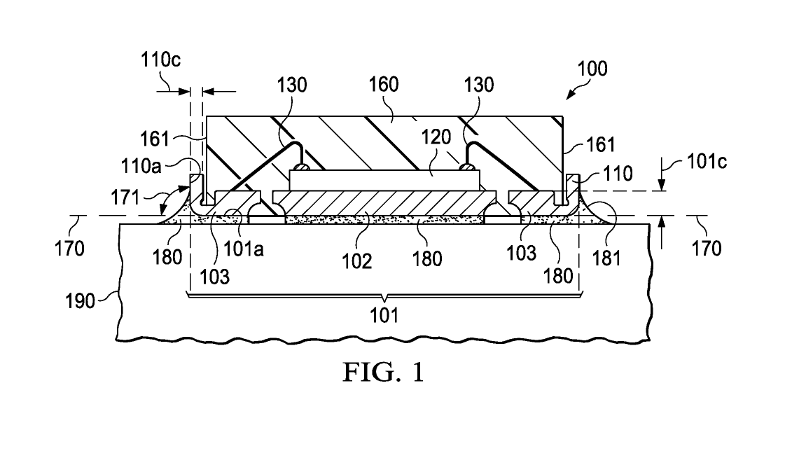

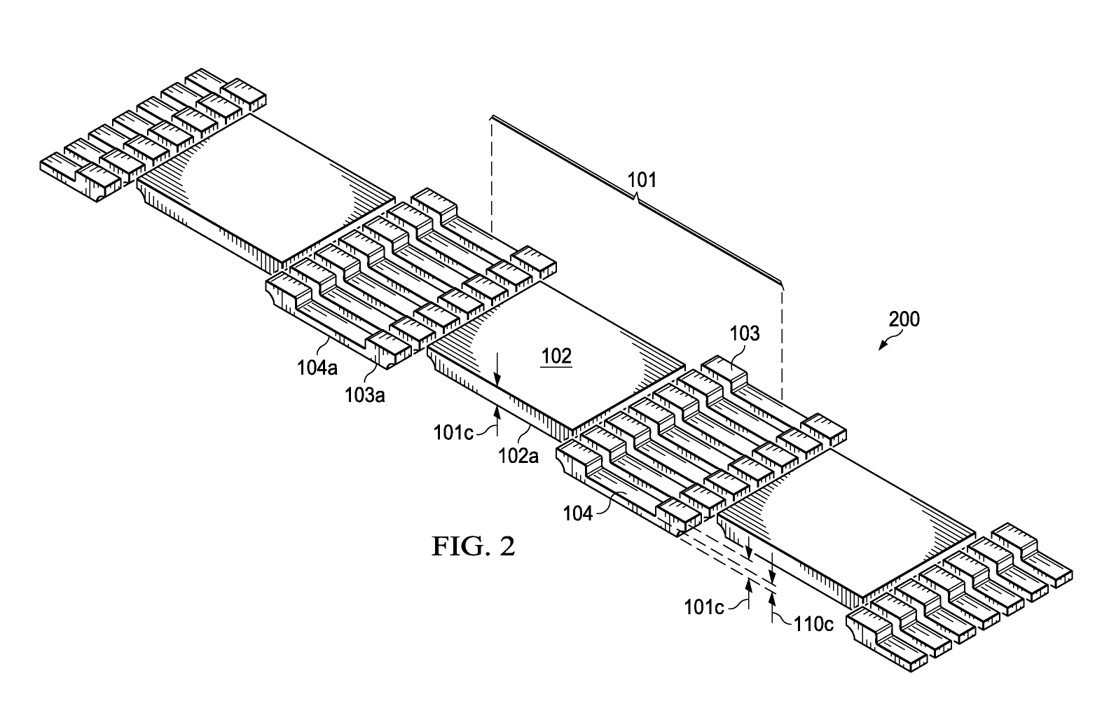

FIG. 1 illustrates an exemplary embodiment of the invention, a packaged semiconductor device 100 with a leadframe 101, which includes bent lead-protrusions 110. Device 100 including the protrusions is shown to be attached to a substrate 190 with solder 180. Metallic leadframe 101 is generally suitable for Quad Flat No-Lead (QFN) and Small Outline No-Lead (SON) type modules; for other devices, leadframe 101 may include other types of configurations. The leadframe includes a pad 102 and a plurality of leads 103; FIG. 2 indicates that the leadframe of a device 100 has at least one set of leads aligned in a row. The leadframe base metal is preferably made of copper or a copper alloy. Alternatively, the base metal may be aluminum, an iron/nickel alloy, or Kovar. One or more surfaces of the leadframe may be metallurgically prepared to facilitate solder attachment, for instance by one or more layers of nickel, palladium, and gold sequentially plated onto the base metal.

Attached to leadframe pad 102 is a semiconductor chip 120, which is connected by bonding wires 130 to the leads 103. Leadframe 101 with the assembled chip 120 and wires 130 are encapsulated by a package 160, which preferably employs as package material an epoxy-based polymeric compound suitable for transfer molding. The package material is shaped by walls 161 so that preferably device 100 is packaged in a housing with hexahedron shape. The one or more sets of leads aligned in rows are positioned along the edges of the package walls.

The sheet of metal used for fabricating leadframe 101 is preferably planar. Consequently, surface 101a of pad 102 and leads 103 are in a common plane 170. Lead surfaces in the common plane remain un-encapsulated by package 160. The exemplary embodiment of FIG. 1 has leads 103 positioned at the edge of package 160.

Each of these leads has as an addition formed as a protrusion 110, which is shaped as a sheet of metal extending away from the package wall 161. In FIG. 1, protrusion 110 has a thickness 110c smaller than thickness 101c of the leads; in other embodiments, thickness 110c may be equal to thickness 101c. The surface 110a of protrusion 110 is solderable. As FIG. 1 shows, protrusions 110 are bent so that surface 110a is bent away from common plane 170 at an angle 171 in the direction towards the device package. It is preferred that the protrusions are bent around the edges of the package. In the example of FIG. 1, surface 110a is bent away from common plane 170 by an approximate right angle so that protrusions 110 are approximately parallel to the package walls. In other embodiments, the angle 171 of the bent protrusion may be acute or obtuse relative to the common plane 170.

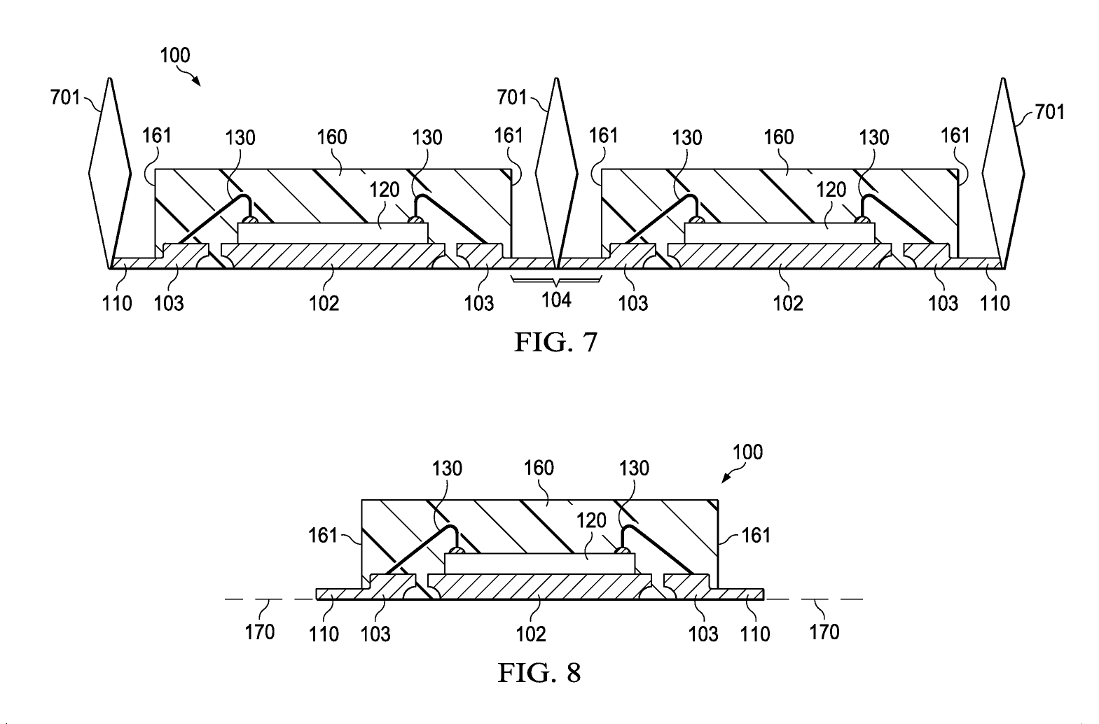

FIG. 2 displays a strip 200 of an exemplary metallic leadframe of the QFN/SON type, which includes a plurality of device sites. The leadframe portion of each device site has been designated 101. Leadframe portion 101 of each device site includes a pad 102 and a plurality of leads 103. At least one set of leads is aligned in a row; for a rectangular pad, there may be four sets of leads arrayed in rows. As FIG. 2 shows, the leads of a row of one device site may be connected by rails 104 to respective leads of an adjacent site. Rails 104 will morph into protrusions 110 after the singulation and bending steps (see FIGS. 7, 9 and 10). The surfaces 104a of rails 104 and the surfaces 103a of aligned leads 103 are on a common plane, which has been designated 170 in FIG. 1. Also pad 102 has a surface on this common plane.

As stated above, the preferred base metal of the leadframe includes copper; alternative metals include aluminum, iron-nickel alloys, and Kovar. Preferred thickness 101c of the leadframe base metal for the exemplary embodiment shown in FIG. 1 is in the range from 0.2 mm to 0.3 mm; other embodiments may use thicker or thinner leadframe metal. From the standpoint of low cost and batch processing, it is preferred to start with sheet metal and fabricate the leadframe as a strip (see FIG. 2) by stamping or etching. As a consequence of the fact that the starting material is a sheet metal, leadframe pad 102, leads 103, and connecting rails 104 are in a common plane, designated 170. It is preferred to flood-plate the stamped leadframe with one or more layers of metals, which promote solder adhesion, such as nickel and palladium. A preferred metallurgy for good solder adhesion is a layer of nickel followed by a layer of palladium followed by a layer of gold. Alternatively, other metal layer may be used, for instance a tin layer, in some applications in combination with other metals such a nickel. In addition, for some devices at least one surface may have a metal layer deposited to enhance thermal conductivity, for instance by a plated layer of silver. The discrete devices are singulated from the leadframe strip by a trimming machine after the encapsulation process (see FIG. 7).

As the exemplary embodiment of FIG. 2 shows, it is preferred that thickness 110c of the rails is smaller than thickness 101c of the leads. Such reduced thickness can be obtained by an etching, planishing, or coining technique. Alternatively, in other embodiments rails 104 may have the same thickness as leads 103.

Another embodiment of the invention is a method for fabricating a packaged semiconductor device with a bent-lead QFN leadframe. The method starts by providing a metallic QFN/SON-type leadframe including a plurality of device sites. An example of a leadframe is illustrated in FIG. 2. Each site includes a pad and a plurality of leads with solderable surfaces. At least one set of leads is aligned in a row and connected by rails to respective leads of an adjacent site; the leads and rails of the row have a surface in a common plane.

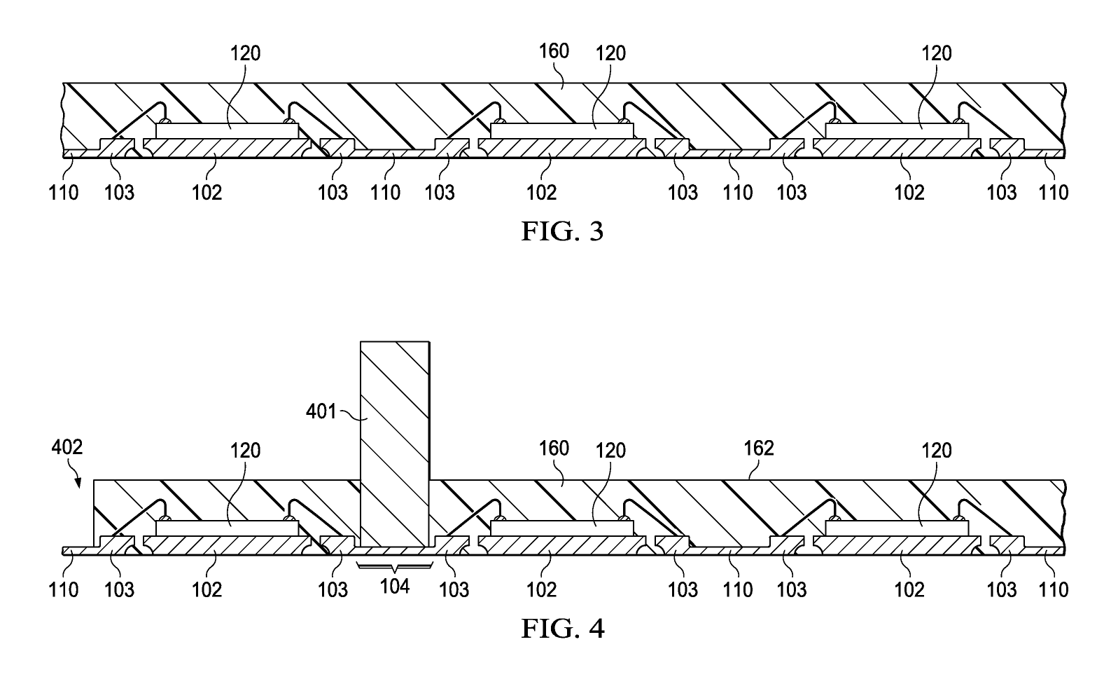

In the fabrication flow, a semiconductor chip is attached on each pad 102 of the leadframe strip and the chip terminals are connected to respective leads by bonding wires. Thereafter, the assembled strip is encapsulated in packages 160, preferably by a transfer molding technique using an epoxy-based polymeric molding compound. Removed from the mold, a portion of the strip may show a cross section as illustrated in FIG. 3. The sheet metal side, which was resting on the bottom mold, remains free of encapsulation compound and is thus un-encapsulated; it is referred to as common plane.

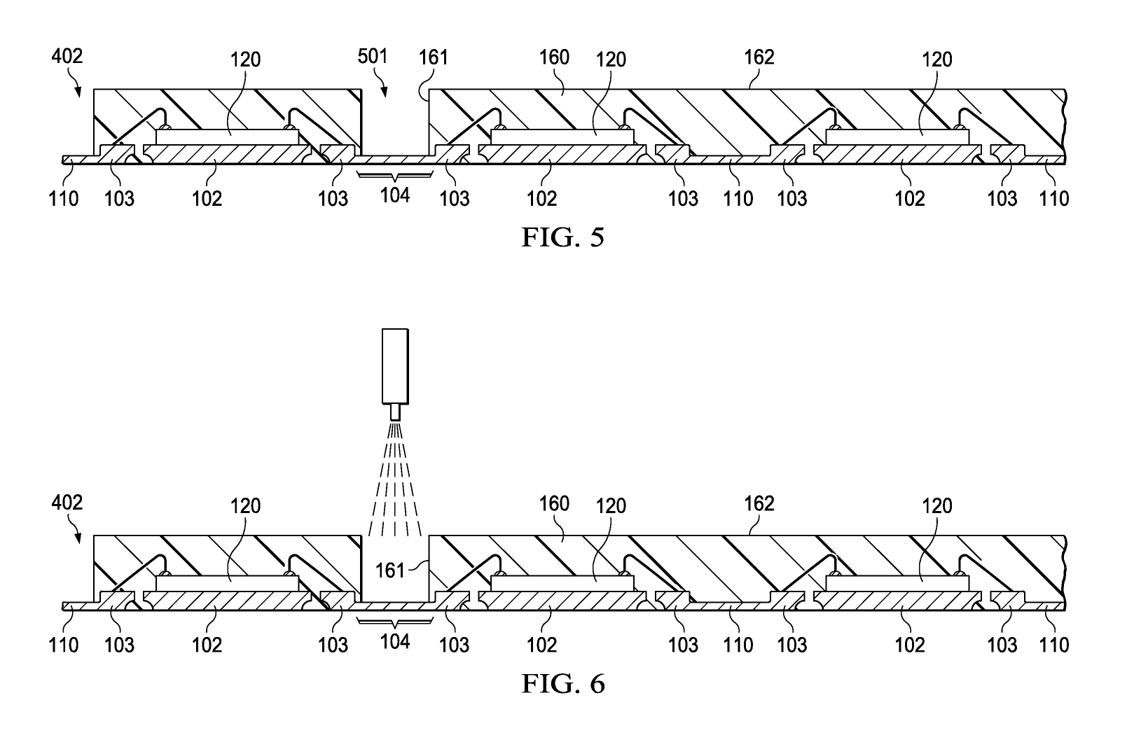

In FIG. 4, a saw 401 is used to cut trenches 402 between adjacent device sites by removing packaging material from the top 162 down until the connecting rails 104 are reached. As FIG. 5 shows, the trench-cutting step creates gaps 501 between adjacent packages and walls 161 of the device packages framing the connecting rails 104. FIG. 5 demonstrates that it is the process step of sawing a trench through the encapsulation material, which lays bare the rails and thus creates the opportunity for forming the protrusions. FIG. 6 illustrates that it is preferred to employ a clean-up and deflashing step after the sawing process using a mechanical saw.

FIG. 7 depicts the process of singulating discrete device packages from the strip by cutting the connecting rails 104 between adjacent sites in approximate halves. The process uses a sharp cutting tool 701; alternatively other separation techniques may be used such as laser beams. The process leaves a respective rail half as a straight protrusion 110 attached to each lead. As FIG. 8 shows, the singulation step creates discrete devices 100 with packages 160 and package walls 161; each lead 103 of the row of leads along the package periphery has an attached straight protrusion 110. The un-encapsulated surfaces of leads and protrusions are in common plane 170.

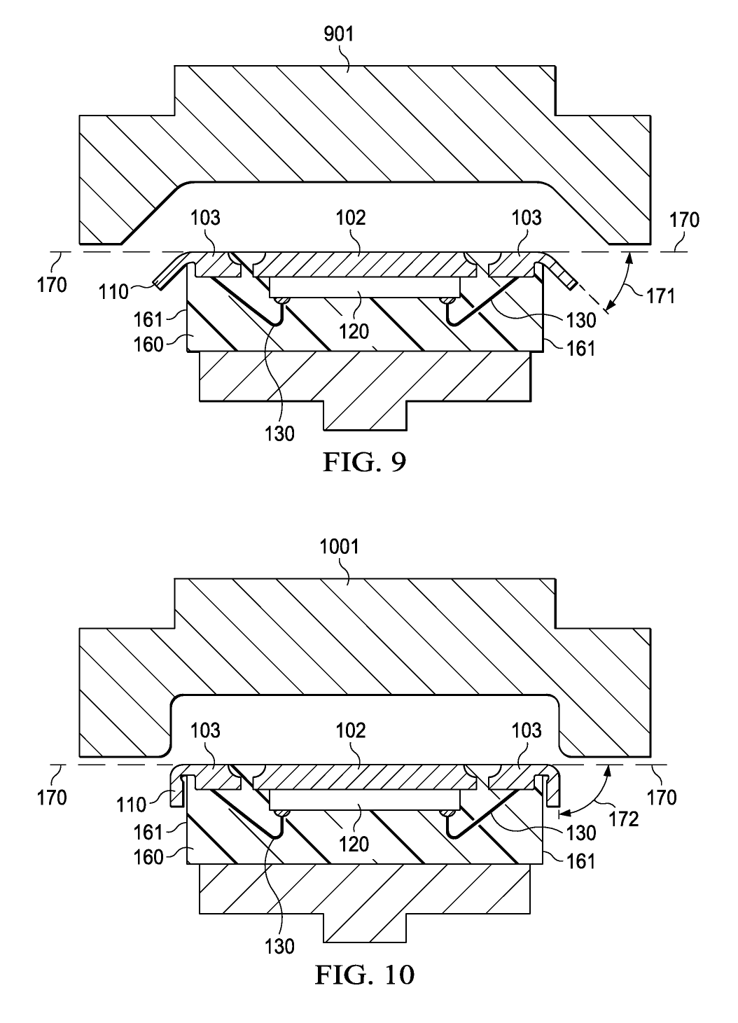

In the next process steps, depicted in FIGS. 9 and 10, the protrusions 110 are bent at an angle 171 away from the common plane 170 towards a package wall 161. The act of bending may be performed in one or more steps. In FIG. 9, a first apparatus 901, which has wings formed at an obtuse angle, is used to apply force acting on the protrusions by stretching the protrusions in order to achieve bending at an acute angle. The outside force by apparatus 901, applied along the length of the protrusions, can stretch the protrusion in the direction of the length, while the dimension of the width is only slightly reduced so that the new shape appears elongated. For elongations small compared to the length, and up to a limit called the elastic limit given by the material characteristic, the amount of elongation is linearly proportional to the force. Pressing on the originally straight protrusions 110, the protrusions 110 are bent at an acute angle away from the common plane 171.

In the next process step, shown in FIG. 10, a second apparatus 1001, which has wings formed at a right angle, is used to apply force acting on the bent protrusions 110. The force is stretching the protrusions further in order to achieve bending of the protrusions at an approximate right angle 172 away from the common plane 170 towards a package wall 161. The inherent material characteristic of many leadframe metals, such as copper, and alloys allow bending at right angles without introducing metal fatigue or microcracks. Since there are no burrs due to the lack of a sawing or trimming operation, the bent protrusions 110 display a smooth surface 110a facing the external world.

Referring now to FIG. 1, as stated above it is preferred to have leadframe 101 including the rails between the device sites metallurgically prepared for easy solder attachment. While it may be sufficient to metallurgically prepare the un-encapsulated leadframe surface 101a, the most practical method is flood plating of the whole leadframe after it has been stamped from the starting metal sheet. The solderable surfaces 101a and 110a are facing the solder 180. During reflow of solder 180, the surface tension of solderable surface 110a is able to pull up a pronounced meniscus 181 and thus form a robust fillet of the solder along protrusion 110. The fillet, in turn, provides a solder attachment of device 100 to substrate 190, which can withstand thermo-mechanical stress and avoid solder fatigue and microcracks.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the invention applies to any semiconductor device family which uses QFN/SON leadframes in strip format. The rails, which connect discrete device sites, can be singulated from the strip into discrete units, which have rail portions left as protrusions of the leads. These protrusions have solderable surfaces and can be bent to facilitate the formation of solder fillets robust enough to withstand thermo-mechanical stress after board attach.

It is therefore intended that the appended claims encompass any such modifications or embodiment.

We claim:

1-7. (canceled)

8. A method for fabricating a semiconductor device comprising the steps of:
providing a strip of metallic leadframes including a plurality of device sites, each site including a pad and a plurality of leads with solderable surfaces, at least one set of leads aligned in a row and connected by rails to respective leads of an adjacent site, the leads and rails of the row having a surface in a common plane, the strip with the assembled sites and connecting rails encapsulated in a packaging material, leaving the common-plane lead and rail surfaces un-encapsulated;
cutting trenches between adjacent sites by removing packaging material until reaching the rails, thus creating sidewalls of device packages connected by rails;
singulating device packages from the strip by severing the connecting rails between adjacent sites in approximate halves, leaving a respective rail half as a straight protrusion attached to each lead; and
bending the protrusions at an angle away from the common plane towards the package sidewall.

9. The method of claim 8 wherein the protrusion are bent around the edge of the package.

10. The method of claim 9 wherein the angle of the bent protrusions approximates a right angle relative to the lead.

11. The method of claim 8 wherein the connecting rails have a thickness smaller than the thickness of the leads.

12. The method of claim 11 wherein the lead protrusions resemble pieces of metal sheets.

13. The method of claim 8 wherein the package is shaped as a hexahedron and the package sidewalls are hexahedron sidewalls.

14. The method of claim 8 wherein the step of providing further includes, for each site, a semiconductor chip assembled on the pad and connected to respective leads.

15. The method of claim 8 wherein the step of bending includes the step of bending the straight protrusions at an acute angle away from the common plane towards a package sidewall, using an apparatus having wings formed at an obtuse angle.

16. The method of claim 8 wherein the step of bending includes the step of bending the protrusions at an approximate right angle away from the common plane towards a package sidewall, using an apparatus having wings formed at a right angle.

17. The method of claim 8 wherein the step of cutting uses a saw rotating through the packaging material followed by a clean-up step.
